(19) United States
(12) Patent Application Publication
(10) Pub. No.: US 2006/0118880 A1
(43) Pub. Date: Jun. 8, 2006

(54) Semiconductor device including field-effect transistor

(75) Inventor: Taiki Komoda, Yokohama-shi (JP)

Correspondence Address: FOLEY AND LARDNER LLP;SUITE 500, 3000 K STREET NW, WASHINGTON, DC, 20007, US

(73) Assignee: KABUSHIKI KAISHA TOSHIBA

(21) Appl. No.: 11/196,498

(22) Filed: Aug. 4, 2005

(30) Foreign Application Priority Data
Dec. 8, 2004 (JP) 2004-355775

(51) Int. Cl. H01L 29/94

(52) U.S. Cl. 257/369

(57) ABSTRACT

A semiconductor device includes a semiconductor region, source and drain regions, gate insulating film, and gate electrode. The semiconductor region has a plane orientation of (001). The source and drain regions are formed away from each other in the semiconductor region, and a channel region is formed in the semiconductor region between the source and drain regions. The channel length direction of the channel region is set along the direction of <100> of the semiconductor region. Tensile stress is produced in the channel length direction. The gate insulating film is formed on the semiconductor region between the source and drain regions. The gate electrode is formed on the gate insulating film.

### CROSS-REFERENCE TO RELATED APPLICATIONS

This application is based upon and claims the benefit of priority from prior Japanese Patent Application No. 2004-355775, filed Dec. 8, 2004, the entire contents of which are incorporated herein by reference.

### BACKGROUND OF THE INVENTION

1. Field of the Invention

The present invention relates to a semiconductor device used in, e.g., a complementary metal oxide film semiconductor (CMOS).

2. Description of the Related Art

To increase the mobility of a p-channel MOS field-effect transistor (referred to as a pMOS transistor hereinafter) and an n-channel MOS field-effect transistor (referred to as an nMOS transistor hereinafter) forming a CMOS, the plane orientation of the substrate or the channel direction is changed, or lattice strain is applied. For example, a silicon-germanium layer serving as a channel increases the hole mobility by compressive stress in the pMOS transistor, and a silicon layer serving as a channel increases the electron mobility by tensile stress in the nMOS transistor (e.g., Jpn. Pat. Appln. KOKAI Publication No. 11-340337).

Unfortunately, the above-mentioned methods of changing the plane orientation of the substrate, changing the channel direction, and applying lattice strain have the following problems.

(1) Change of Plane Orientation of Substrate

For example, when a (011) wafer is used, the mobility of the hole rises, but the mobility of the electron lowers. In addition, since rotational symmetry of order four on the wafer cannot be presented, a conventional circuit design cannot be used. This greatly increases the circuit design effort.

(2) Change of Channel Direction

Similar to the change of the plane orientation of the substrate, it is impossible to simultaneously raise the mobility of the electron and hole. To raise the mobility of both the electron and hole, therefore, it is necessary to separately form the two transistors. This complicates the process.

(3) Application of Lattice Strain

Uniaxial stress generates local strain in the channel direction. However, when uniaxial compression or tensile stress is applied to nMOS and pMOS transistors formed on a normally used (001) wafer having a <110> channel direction, the direction in which the mobility increases or decreases in the nMOS transistor differs from that in the pMOS transistor. To raise the mobility of both the electron and hole, therefore, it is necessary to separately form the two transistors. This also complicates the process.

In future generations in which the yield presumably lowers due to the progress of micropatterning, it is extremely difficult to use a complicated process in order to increase the mobility.

### BRIEF SUMMARY OF THE INVENTION

A semiconductor device of the present invention according to a first aspect comprises a (001) semiconductor region, a source region and a drain region formed away from each other in the semiconductor region, a channel region being formed in the semiconductor region between the source region and the drain region, a channel length direction of the channel region being set in a direction of <100> of the semiconductor region, and tensile stress being produced in the channel length direction, a gate insulating film formed on the semiconductor region between the source region and the drain region, and a gate electrode formed on the gate insulating film.

A semiconductor device of the present invention according to a second aspect comprises a (001) semiconductor region, a source region and a drain region formed away from each other in the semiconductor region, a channel length direction connecting the source region and the drain region being set along a direction of <100> of the semiconductor region, a gate insulating film formed on the semiconductor region between the source region and the drain region, a gate electrode formed on the gate insulating film, and an insulating film which is formed on the source region, the drain region, and the gate electrode, and produces tensile stress in the channel length direction connecting the source region and the drain region in the semiconductor region.

A semiconductor device of the present invention according to a third aspect comprises a (001) semiconductor region, a source region and a drain region formed away from each other in the semiconductor region, a channel length direction connecting the source region and the drain region being set in a direction of <100> of the semiconductor region, a gate insulating film formed on the semiconductor region between the source region and the drain region, a gate electrode formed on the gate insulating film, and an element isolation region formed in a trench formed in the semiconductor region, and including a silicon nitride film, the silicon nitride film being in contact with at least a portion of the source region and the drain region.

A semiconductor device of the present invention according to a fourth aspect comprises a (001) semiconductor region, a source region and a drain region formed away from each other in the semiconductor region, a channel length direction connecting the source region and the drain region being set in a direction of <100> of the semiconductor region, a gate insulating film formed on the semiconductor region between the source region and the drain region, and a gate electrode formed on the gate insulating film and containing an impurity element which expands the gate electrode upon annealing.

A semiconductor device of the present invention according to a fifth aspect comprises a (001) semiconductor region, a source region and a drain region formed away from each other in the semiconductor region, the source region and the drain region having a silicon compound containing an element having a lattice constant smaller than that of silicon, and a channel length direction connecting the source region and the drain region being set in a direction of <100> of the semiconductor region, a gate insulating film formed on the semiconductor region between the source region and the drain region, and a gate electrode formed on the gate insulating film.

A semiconductor device fabrication method of the present invention according to a sixth aspect comprises forming a gate electrode above a (001) semiconductor region, forming a source region and a drain region in the semiconductor region along a direction of <100> of the semiconductor region so as to sandwich the semiconductor region below the gate electrode, and forming, on the source region, the drain region, and the gate electrode, an insulating film which produces tensile stress in a channel length direction connecting the source region and the drain region in the semiconductor region.

A semiconductor device fabrication method of the present invention according to a seventh aspect comprises forming trenches in a (001) semiconductor region, forming a silicon nitride film in contact with the semiconductor region in the trenches, forming a gate electrode above the semiconductor region between the trenches, and forming a source region and a drain region in the semiconductor region along a direction of <100>of the semiconductor region so as to sandwich the semiconductor region below the gate electrode.

A semiconductor device fabrication method of the present invention according to an eighth aspect comprises forming, above a (001) semiconductor region, a gate electrode into which an impurity element which expands upon annealing is doped, annealing the gate electrode, and forming a source region and a drain region in the semiconductor region along a direction of <100> of the semiconductor region so as to sandwich the semiconductor region below the gate electrode.

A semiconductor device fabrication method of the present invention according to a ninth aspect comprises forming a gate electrode above a (001) semiconductor region, forming a sidewall insulating film on side walls of the gate electrode, forming grooves in the semiconductor region on sides of the sidewall insulating film, and forming, in the grooves, a source region and a drain region made of epitaxial layers along a direction of <100> of the semiconductor region so as to sandwich the semiconductor region below the gate electrode.

### BRIEF DESCRIPTION OF THE SEVERAL VIEWS OF THE DRAWING

FIG. 1 is a sectional view showing the structure of a semiconductor device of a first embodiment of the present invention;

FIG. 2 is a graph showing the relationship between the uniaxial stress in the channel length direction and the hole mobility at small device of the first to a fourth embodiment of the present invention;

FIG. 3 is a graph showing the relationship between the uniaxial stress in the channel length direction and the electron mobility at small device of the first to a fourth embodiment of the present invention;

FIGS. 4, 5 and 6 are sectional views of steps showing a method of fabricating the semiconductor device of the first embodiment;

FIG. 7 is a sectional view showing the structure of a semiconductor device of a second embodiment of the present invention;

FIGS. 8 and 9 are sectional views of steps showing a method of fabricating the semiconductor device of the second embodiment;

FIG. 10 is a sectional view showing the structure of a semiconductor device of a third embodiment of the present invention;

FIG. 11 is a sectional view of a step showing a method of fabricating the semiconductor device of the third embodiment;

FIG. 12 is a sectional view showing the structure of a semiconductor device of a fourth embodiment of the present invention; and

FIGS. 13 and 14 are sectional views of steps showing a method of fabricating the semiconductor device of the fourth embodiment.

### DETAILED DESCRIPTION OF THE INVENTION

Embodiments of the present invention will be described below with reference to the accompanying drawing. In the following description, the same reference numerals denote the same parts throughout the drawing.

### First Embodiment

First, a pMOS transistor and nMOS transistor included in a semiconductor device of a first embodiment of the present invention will be explained.

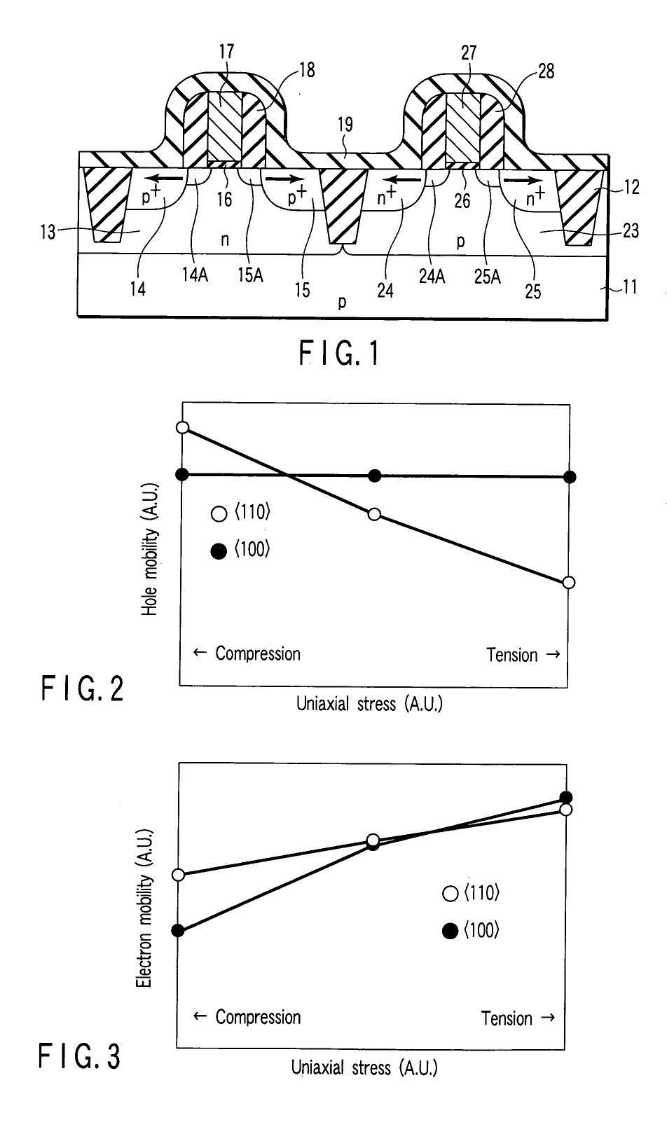

FIG. 1 is a sectional view showing the structure of the semiconductor device of the first embodiment.

Element isolation regions 12 are arranged in a p-type silicon substrate 11. The p-type semiconductor substrate 11 is a (001) wafer. The element isolation regions 12 are made of, e.g., shallow trench isolation (STI) in which a silicon oxide film or the like is buried in trenches formed in the p-type semiconductor substrate 11. The element isolation regions 12 electrically insulate and isolate elements (transistors) formed on the p-type semiconductor substrate 11, thereby defining element regions where these elements are formed.

The structure of a pMOS transistor will be described below.

An n-type well region 13 is formed on the p-type silicon semiconductor substrate 11. In the surface region of the n-type well region 13, a source region 14 made of a p⁺-type semiconductor region and a drain region 15 which is also a p⁺-type semiconductor region are formed away from each other. In addition, between the source region 14 and drain region 15, extension regions 14A and 15A each made of a p⁻-type semiconductor region having an impurity concentration lower than that of the source region 14 and drain region 15 are formed. A gate insulating film 16 is formed on the n-type well region 13 between the source region 14 and drain region 15. A gate electrode 17 is formed on the gate insulating film 16. A channel region is formed in the n-type well region 13 below the gate electrode 17. The channel length direction (source-drain direction) of this channel region is set in the direction of <100> of the p-type semiconductor substrate 11.

A sidewall insulating film 18 which is a stacked film of a silicon nitride film and silicon oxide film is formed on the side surfaces of the gate electrode 17. In addition, a liner film 19 is formed on the source region 14, drain region 15, gate electrode 17, sidewall insulating film 18, and element isolation regions 12. The liner film 19 is an insulating film, e.g., a silicon nitride film, which applies tensile stress in the channel length direction (source-drain direction) of the channel region. Examples of the silicon nitride film which applies tensile stress like this are an SiN film (HCD [hexa-chloro-disilane]-SiN film) formed by thermal CVD by using a gas mixture of HCD/NH₃, and an SiN film formed by plasma CVD which forms more Si—H bonds than N—H bonds.

The structure of an nMOS transistor will be described below.

A p-type well region 23 is formed on the p-type silicon semiconductor substrate 11. In the surface region of the p-type well region 23 in element regions, a source region 24 made of an n⁺-type semiconductor region and a drain region 25 which is also an n⁺-type semiconductor region are formed away from each other. In addition, extension regions 24A and 25A each made of an n-type semiconductor region are formed between the source region 24 and drain region 25. A gate insulating film 26 is formed on the p-type well region 23 between the source region 24 and drain region 25. A gate electrode 27 is formed on the gate insulating film 26. A channel region is formed in the p-type well region 23 below the gate electrode 27. The channel length direction (source-drain direction) of this channel region is set in the direction of <100> of the p-type semiconductor substrate 11.

A sidewall insulating film 28 which is a stacked film of a silicon nitride film and silicon oxide film is formed on the side surfaces of the gate electrode 27. In addition, the liner film 19 described above is formed on the source region 24, drain region 25, gate electrode 27, sidewall insulating film 28, and element isolation regions 12. The liner film 19 is an insulating film, e.g., a silicon nitride film, which applies tensile stress in the channel length direction (source-drain direction) of the channel region in this transistor as well.

In the PMOS transistor described above, the channel length direction is set in the direction of <100> of the semiconductor substrate, and the liner film (e.g., a silicon nitride film) formed on the source region and drain region applies uniaxial tensile stress in the channel length direction.

FIG. 2 shows the relationship between the uniaxial stress (abscissa) in a direction parallel to the channel and the hole mobility (ordinate) in the PMOS transistor. A direction perpendicular to the channel is the same as an ordinary microdevice. As shown in FIG. 2, when the channel length direction is <100>, the hole mobility in the microdevice remains almost unchanged or slightly increases even if the tensile stress increases. On the other hand, the channel length direction is in many cases <110> in conventional devices, and the hole mobility lowers as the tensile stress increases. In the pMOS transistor of the first embodiment of the present invention, therefore, a (001) silicon semiconductor substrate is used, and the channel length direction is set in the direction of <100> of this semiconductor substrate. Consequently, even if tensile stress is applied in the channel length direction, the hole mobility does not decrease but is higher than that when no tensile stress is applied or that when the channel length direction is <110> while tensile stress is applied. Note that the mobility increasing effect when tensile stress is applied is larger than that when no tensile stress is applied. From the foregoing, the transistor characteristics of the pMOS transistor do not deteriorate even if tensile stress is applied in the channel length direction.

In the nMOS transistor as well, the channel length direction is set in the direction of <100> of the semiconductor substrate, and the liner film (e.g., a silicon nitride film) formed on the source region and drain region applies uniaxial tensile stress in the channel length direction.

FIG. 3 shows the relationship between the uniaxial stress (abscissa) and the electron mobility (ordinate) in the nMOS transistor. As shown in FIG. 3, when the channel length direction is <100>, the electron mobility increases as the tensile stress increases. Even when the channel length direction is <110> as in the prior art, the electron mobility similarly increases as the tensile stress increases. Accordingly, in the nMOS transistor of the first embodiment, even when the channel length direction is set in the direction of <100> of the semiconductor substrate, the electron mobility does not decrease, and substantially the same transistor characteristics as when the channel length direction is <110> can be maintained.

As shown in FIG. 2 described above, in the pMOS transistor which uses the (001) wafer and in which the channel length direction is <100>, the mobility changing effect by strain produced by tensile stress is small, and the hole mobility is higher than that in the pMOS transistor in which the channel length direction is <110>. Also, as shown in FIG. 3, in the nMOS transistor which uses the (001) wafer and in which the channel length direction is <100>, the mobility increasing effect equal to or larger than that in the nMOS transistor in which the channel length direction is <110>is obtained by strain produced by tensile stress.

A method of fabricating the pMOS transistor and nMOS transistor included in the semiconductor device of the first embodiment will be explained below.

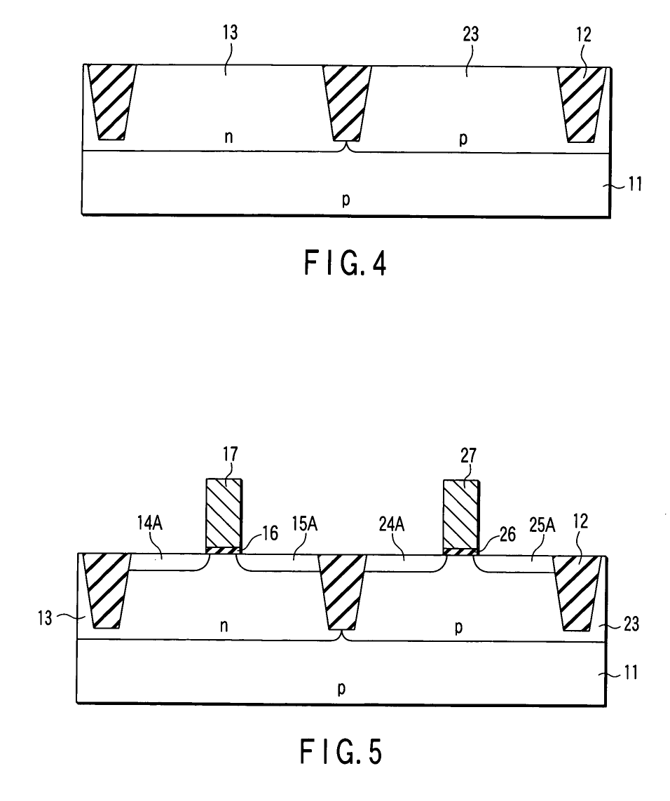

First, trenches are formed in a (001) silicon semiconductor substrate 11 by RIE. As shown in FIG. 4, element isolation regions 12 are formed by burying an insulating film such as a silicon oxide film in these trenches. In addition, an n-type well region 13 and p-type well region 23 are formed by ion implantation in those portions of the p-type semiconductor substrate 11, which function as element regions between the element isolation regions 12.

Then, a silicon oxide film serving as a gate insulating film is formed on the n-type well region 13 and p-type well region 23 by thermal oxidation. On this silicon oxide film, a conductive film, e.g., a polysilicon film, serving as a gate electrode is formed by CVD. As shown in FIG. 5, gate insulating films 16 and 26 and gate electrodes 17 and 27 are formed by photolithography. In addition, extension regions 14A and 15A are formed by ion implantation in the n-type well region 13 near the two side surfaces of the gate electrode 17. Similarly, extension regions 24A and 25A are formed by ion implantation in the p-type well region 23 near the two side surfaces of the gate electrode 27.

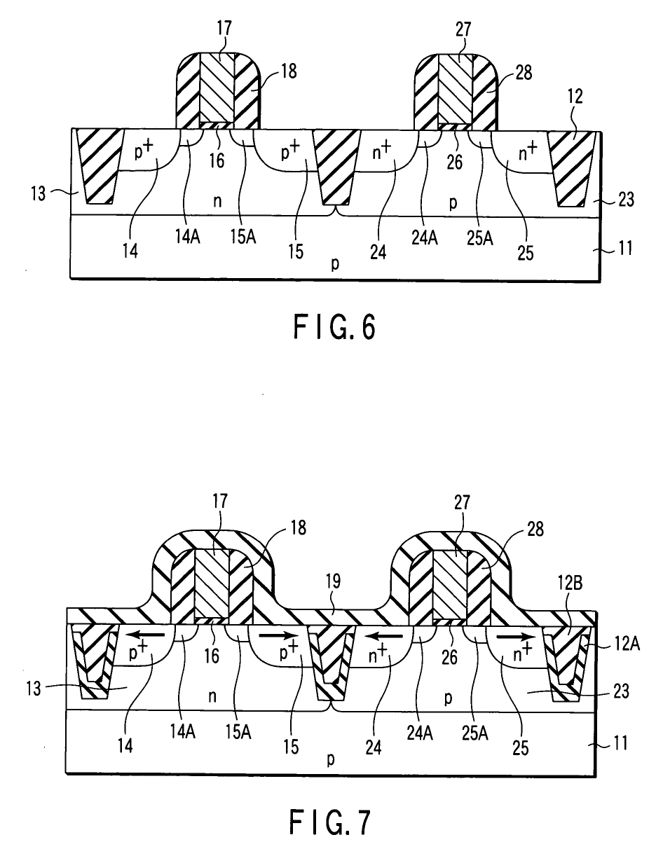

After that, an insulating film such as a silicon oxide film is deposited on the structure shown in FIG. 5, i.e., on the gate electrodes 17 and 27 and on the p-type semiconductor substrate 11. As shown in FIG. 6, the deposited silicon oxide film is anisotropically etched by RIE to form sidewall insulating films 18 and 28 on the side surfaces of the gate electrodes 17 and 27, respectively. In addition, in the p-type semiconductor substrate 11 outside the sidewall insulating film 18, a source region 14 and drain region 15 each made of a p⁺-type semiconductor region are formed by ion implantation. Likewise, in the p-type semiconductor substrate 11 outside the sidewall insulating film 28, a source region 24 and drain region 25 each made of an n⁺-type semiconductor region are formed by ion implantation. The source region 14 and drain region 15 are so arranged that the channel length direction (source-drain direction) connecting the source region 14 and drain region 15 is set along the direction of <100> of the p-type semiconductor substrate 11. Similarly, the source region 24 and drain region 25 are so arranged that the channel length direction (source-drain direction) connecting the source region 24 and drain region 25 is set along the direction of <100> of the p-type semiconductor substrate 11.

After that, a liner film 19 which applies tensile stress in the channel length direction (source-drain direction) of the channel region is formed on the structure shown in FIG. 6, i.e., on the source regions 14 and 24, drain regions 15 and 25, gate electrodes 17 and 27, sidewall insulating films 18 and 28, and element isolation regions 12. The liner film 19 is an insulating film such as a silicon nitride film. The silicon nitride film which applies tensile stress like this is formed by thermal CVD by using a gas mixture of HCD/NH₃, or by plasma CVD. In this manner, the semiconductor device shown in FIG. 1 is fabricated.

In the first embodiment as explained above, a (001) semiconductor substrate is used, the channel length direction is set in the direction of <100> of this semiconductor substrate, and a liner film formed on a source region and drain region is used to generate tensile stress in the channel length direction of the channel region. This makes it possible to increase the mobility in a pMOS transistor and nMOS transistor formed on the same semiconductor substrate.

### Second Embodiment

A pMOS transistor and nMOS transistor included in a semiconductor device of a second embodiment of the present invention will be described below. The same reference numerals as in the structure of the first embodiment denote the same parts, so an explanation thereof will be omitted, and only different portions will be described below.

FIG. 7 is a sectional view showing the structure of the semiconductor device of the second embodiment.

Element isolation regions formed by STI are arranged in an n-type well region 13 and p-type well region 23 on a p-type silicon semiconductor substrate 11. This STI is obtained by burying a silicon nitride film 12A and silicon oxide film 12B in trenches formed in the semiconductor substrate 11 or in the n-type well region 13 and p-type well region 23. The STI has the following structure. The trenches are formed in the p-type silicon semiconductor substrate 11, and the silicon nitride film 12A is formed on those inner surfaces of the trenches, to which silicon regions are exposed. More specifically, the silicon nitride film 12A is formed in the trenches so as to contact at least a portion of silicon regions such as source regions 14 and 24, drain regions 15 and 25, the n-type well region 13, and the p-type well region 23. On the silicon nitride film 12A in these trenches, the silicon oxide film 12B is formed to be buried in the trenches. The rest of the structures of the pMOS transistor and nMOS. transistor are the same as in the first embodiment.

The STI of the second embodiment has the silicon nitride film in contact with at least a portion of the silicon semiconductor regions. In the pMOS transistor and nMOS transistor having this STI, stress is generated from the channel region to the STI. Accordingly, tensile stress is applied in the channel length direction (source-drain direction) of the channel region. Note that the silicon nitride film alone may also be buried in the STI.

In the pMOS transistor of the second embodiment, the channel length direction is set in the direction of <100> of the semiconductor substrate, and the STI having the silicon nitride film in contact with a silicon region applies uniaxial tensile stress in the channel length direction. As in the first embodiment, the relationship between the uniaxial stress (abscissa) and the hole mobility (ordinate) in the pMOS transistor is as shown in FIG. 2. The hole mobility in the channel of the PMOS transistor remains almost unchanged or slightly increases even when the tensile stress increases. This increases the hole mobility compared to that when no tensile stress is applied or that when the channel length direction is <110> while tensile stress is applied. Accordingly, the transistor characteristics of the pMOS transistor do not deteriorate even if tensile stress is applied in the channel length direction.

In the nMOS transistor of the second embodiment as well, the channel length direction is set in the direction of <100> of the semiconductor substrate, and the STI having the silicon nitride film in contact with a silicon region applies uniaxial tensile stress in the channel length direction. As in the first embodiment, the relationship between the uniaxial stress (abscissa) and the electron mobility (ordinate) in the nMOS transistor is as shown in FIG. 3. The electron mobility in the channel of the nMOS transistor increases as the tensile stress increases, and changes in substantially the same way as when the channel length direction is <110>. In the nMOS transistor, therefore, substantially the same transistor characteristics as when the channel length direction is <110> can be maintained.

A method of fabricating the pMOS transistor and nMOS transistor included in the semiconductor device of the second embodiment will be explained below.

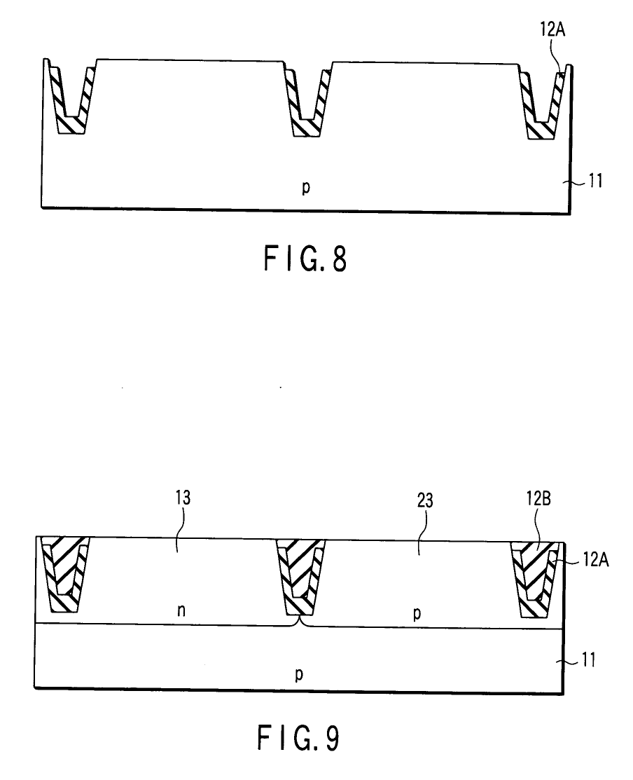

First, trenches are formed in a (001) p-type silicon semiconductor substrate 11 by RIE. Subsequently, as shown in FIG. 8, a silicon nitride film 12A is formed by CVD on those inner surfaces of the trenches, to which silicon regions are exposed. In addition, as shown in FIG. 9, a silicon oxide film 12B is formed by CVD on the silicon nitride film 12A in these trenches so as to be buried in the trenches.

After that, an n-type well region 13 and p-type well region 23 are formed by ion implantation in the p-type semiconductor substrate 11 between element isolation regions made up of the silicon nitride film 12A and silicon oxide film 12B. The subsequent steps are the same as in the first embodiment shown in FIGS. 5 and 6.

In the second embodiment as described above, a (001) semiconductor substrate is used, the channel length direction is set in the direction of <100> of this semiconductor substrate, and STI having a silicon nitride film in contact with a silicon region generates tensile stress in the channel length direction of the channel region. This makes it possible to increase the mobility in a PMOS transistor and nMOS transistor formed on the same semiconductor substrate.

### Third Embodiment

A PMOS transistor and nMOS transistor included in a semiconductor device of a third embodiment of the present invention will be described below. The same reference numerals as in the structure of the first embodiment denote the same parts, so an explanation thereof will be omitted, and only different portions will be described below.

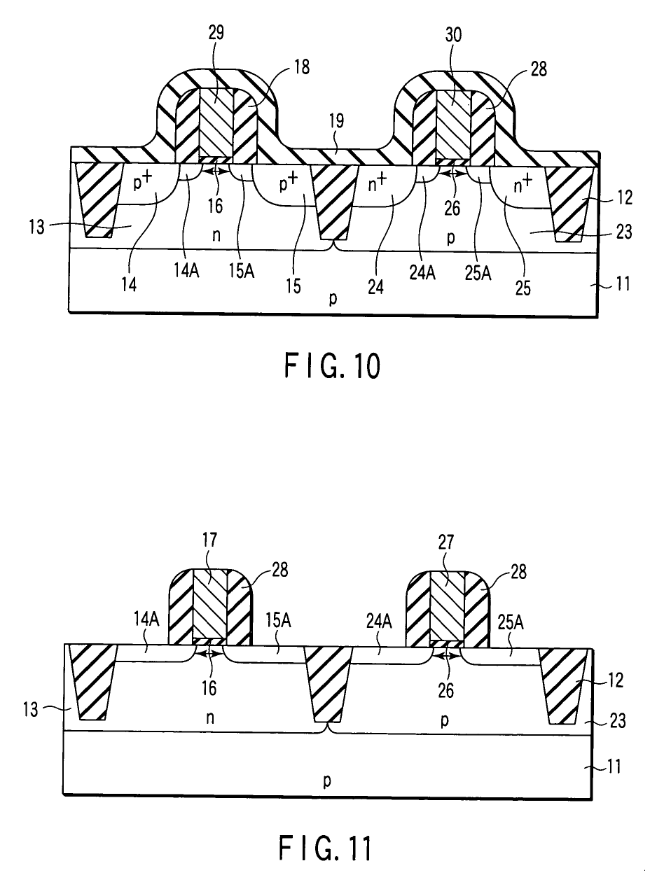

FIG. 10 is a sectional view showing the structure of the semiconductor device of the third embodiment.

A gate insulating film 16 is formed on an n-type well region 13 between a source region 14 and drain region 15, and a gate electrode 29 is formed on the gate insulating film 16. Also, a gate insulating film 26 is formed on a p-type well region 23 between a source region 24 and drain region 25, and a gate electrode 30 is formed on the gate insulating film 26.

The gate electrodes 29 and 30 are made of, e.g., polysilicon. A predetermined impurity (e.g., arsenic [As] or germanium [Ge]) by which this polysilicon expands upon annealing is doped in the polysilicon by ion implantation or the like. When the polysilicon is annealed, the gate electrodes 29 and 30 made of the polysilicon expand. As a consequence, tensile stress is generated in the channel length direction (source-drain direction) in the n-type well region 13 and p-type well region 23 (channel regions) below the gate electrodes 29 and 30, respectively.

In the pMOS transistor of the third embodiment, the channel length direction is set in the direction of <100> of the semiconductor substrate, and an impurity which expands the gate electrode upon annealing is doped in the gate electrode. Therefore, uniaxial tensile stress is applied in the channel length direction by expansion of the gate electrode upon annealing. As in the first embodiment, as shown in FIG. 2, the hole mobility in the channel of the pMOS transistor remains almost unchanged or slightly increases even when the tensile stress increases. This increases the hole mobility compared to that when no tensile stress is applied or tensile stress is applied that when the channel length direction is <110>. Accordingly, the transistor characteristics of the pMOS transistor do not deteriorate even if tensile stress is applied in the channel length direction.

In the nMOS transistor of the third embodiment as well, the channel length direction is set in the direction of <100> of the semiconductor substrate, and an impurity which expands the gate electrode upon annealing is doped in the gate electrode. Therefore, uniaxial tensile stress is applied in the channel length direction by expansion of the gate electrode upon annealing. As in the first embodiment, as shown in FIG. 3, the electron mobility in the channel of the nMOS transistor increases as the tensile stress increases, and changes in substantially the same way as when the channel length direction is <110>. In the nMOS transistor, therefore, substantially the same transistor characteristics as when the channel length direction is <110> can be maintained.

A method of fabricating the pMOS transistor and nMOS transistor included in the semiconductor device of the third embodiment will be explained below.

In the same steps as in the first embodiment shown in FIGS. 4 and 5, gate electrodes 29 and 30 made of, e.g., polysilicon are formed, and extension regions 14A, 15A, 24A, and 25A are formed by ion implantation.

Then, an insulating film such as a silicon oxide film is deposited on the structure shown in FIG. 5, i.e., on gate electrodes 17 and 27 and on a p-type semiconductor substrate 11. The deposited silicon oxide film is anisotropically etched by RIE, thereby forming sidewall insulating films 18 and 28 on the side surfaces of the gate electrodes 29 and 30, respectively.

A predetermined impurity (e.g., arsenic [As] or germanium [Ge] by which polysilicon expands is doped in the gate electrodes 29 and 30 by ion implantation. The gate electrodes 29 and 30 made of polysilicon are then expanded by annealing. As a consequence, tensile stress is produced in the channel length direction (source-drain direction) in a n-type well region 13 and p-type well region 23 (channel regions) below the gate electrodes 29 and 30, respectively.

After that, as in the first embodiment shown in FIG. 6, in the p-type semiconductor substrate 11 outside the sidewall insulating film 18, a source region 14 and drain region 15 each made of a p⁺-type semiconductor region are formed by ion implantation. Likewise, in the p-type semiconductor substrate 11 outside the sidewall insulating film 28, a source region 24 and drain region 25 each made of an n⁺-type semiconductor region are formed by ion implantation. The other steps are also the same as the steps in the first embodiment. Note that in the third embodiment, the step of expanding the gate electrodes 29 and 30 by annealing is performed before the source and drain regions are formed. However, this annealing step may also be performed before the source and drain regions are formed.

In the third embodiment as described above, a (001) semiconductor substrate is used, the channel length direction is set in the direction of <100> of this semiconductor substrate, and a gate electrode containing an impurity which expands the gate electrode upon annealing is formed, thereby producing tensile stress in the channel length direction of the channel region. This makes it possible to increase the mobility in a PMOS transistor and nMOS transistor formed on the same semiconductor substrate.

### Fourth Embodiment

A pMOS transistor and nMOS transistor included in a semiconductor device of a fourth embodiment of the present invention will be described below. The same reference numerals as in the structure of the first embodiment denote the same parts, so an explanation thereof will be omitted, and only different portions will be described below.

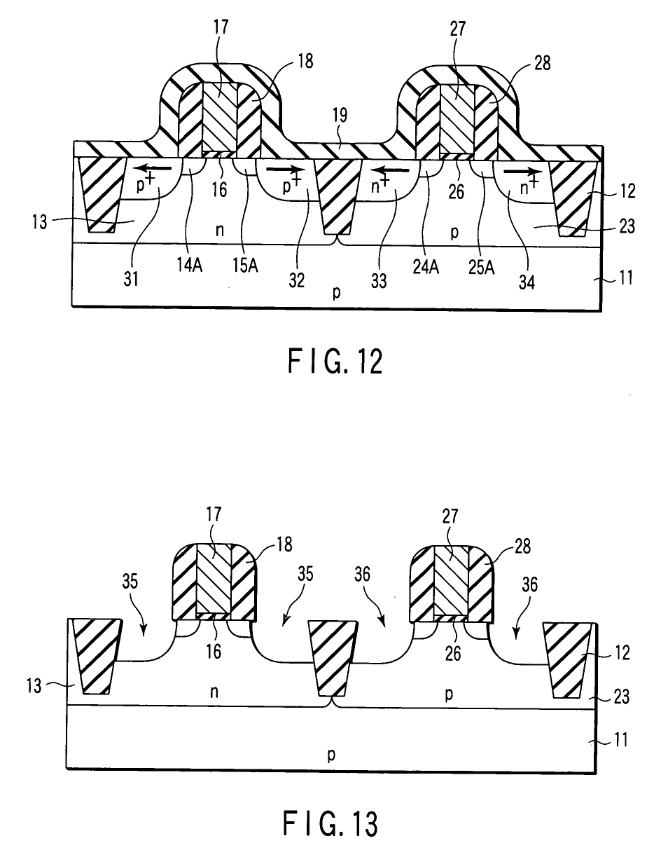

FIG. 12 is a sectional view showing the structure of the semiconductor device of the fourth embodiment.

In a pMOS transistor, a source region 31 and drain region 32 each made of an n⁺-type semiconductor region is formed away from each other in the surface region of an n-type well region 13. In an nMOS transistor, a source region 33 and drain region 34 each made of a p⁺-type semiconductor region is formed away from each other in the surface region of a p-type well region 23.

The source regions 31 and 33 and drain regions 32 and 34 are formed by the following fabrication method. After sidewall insulating films 18 and 28 are formed on the side surfaces of gate electrodes 17 and 27, the n-type well region 13 and p-type well region 23 on the sides of the sidewall insulating films 18 and 28 are isotropically etched to form grooves. Subsequently, an epitaxial layer serving as a source region or drain region is formed in the grooves by selective epitaxial growth. Note that although in this embodiment the step of forming the grooves is performed by isotropic etching, anisotropic etching may also be used.

The source regions 31 and 33 and drain regions 32 and 34 are made of a silicon compound, e.g., silicon carbide (SiC), which contains in silicon an element having a lattice constant smaller than that of silicon. When the source regions 31 and 33 and drain regions 32 and 34 thus contain silicon carbide, stress is produced in the source region from the vicinity of the channel region toward the center of the source region, and stress is produced in the drain region from the vicinity of the channel region toward the center of the drain region. As a consequence, tensile stress is applied in the channel length direction (source-drain direction) of the channel region in each of the PMOS transistor and nMOS transistor.

In the pMOS transistor of the fourth embodiment, the channel length direction is set in the direction of <100> of the semiconductor substrate, and the source and drain regions are made of a silicon compound containing an element having a lattice constant smaller than that of silicon. In this structure, the source and drain regions generate a force with which they contract themselves, and this applies uniaxial tensile stress in the channel length direction of the channel region. As in the first embodiment, as shown in FIG. 2, the hole mobility in the channel of the pMOS transistor remains almost unchanged or slightly increases even when the tensile stress increases. This increases the hole mobility compared to that when no tensile stress is applied or tensile stress is applied that when the channel length direction is <110>. Accordingly, the transistor characteristics of the pMOS transistor do not deteriorate even if tensile stress is applied in the channel length direction.

In the nMOS transistor of the fourth embodiment as well, the channel length direction is set in the direction of <100> of the semiconductor substrate, and the source and drain regions are made of a silicon compound containing an element having a lattice constant smaller than that of silicon. In this structure, the source and drain regions generate a force with which they contract themselves, and this applies uniaxial tensile stress in the channel length direction of the channel region. As in the first embodiment, as shown in FIG. 3, the electron mobility in the channel of the nMOS transistor increases as the tensile stress increases, and changes in substantially the same way as when the channel length direction is <110>. In the nMOS transistor, therefore, substantially the same transistor characteristics as when the channel length direction is <110> can be maintained.

A method of fabricating the pMOS transistor and nMOS transistor included in the semiconductor device of the fourth embodiment will be explained below.

Steps up to the formation of sidewall insulating films 18 and 28 on the side surfaces of gate electrodes 17 and 27, respectively, are the same as in the first embodiment. After the sidewall insulating films 18 and 28 are formed on the side surfaces of the gate electrodes 17 and 27, as shown in FIG. 13, grooves 35 and 36 are formed by isotropically etching an n-type well region 13 and p-type well region 23 on the sides of the sidewall insulating films 18 and 28, respectively.

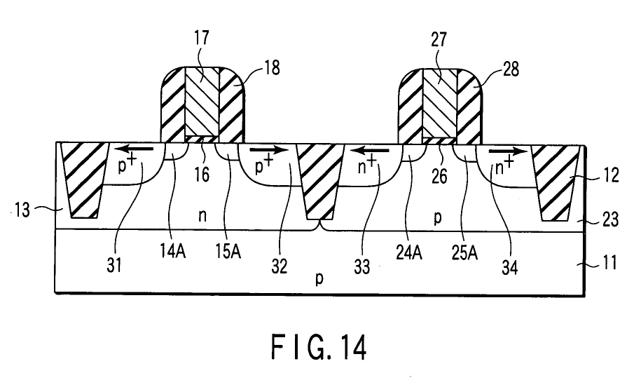

Subsequently, as shown in FIG. 14, epitaxial layers serving as a source region 31 and drain region 32 are formed in the grooves 35 by selective epitaxial growth. Similarly, epitaxial layers serving as a source region 33 and drain region 34 are formed in the grooves 36 by selective epitaxial growth. The source region 31 and drain region 32 are p⁺-type semiconductor regions, and the source region 33 ad drain region 34 are n⁺-type semiconductor regions. The source regions 31 and 33 and drain regions 32 and 34 are made of a silicon compound, e.g., silicon carbide (SiC), which contains in silicon an element having a lattice constant smaller than that of silicon.

In this structure, the source region 31 and drain region 32 are so arranged that the channel length direction (source-drain direction) connecting the source region 31 and drain region 32 is set along the direction of <100> of a p-type semiconductor substrate 11. Likewise, the source region 33 and drain region 34 are so arranged that the channel length direction (source-drain direction) connecting the source region 33 and drain region 34 is set along the direction of <100> of the p-type semiconductor substrate 11. The subsequent steps are the same as in the first embodiment.

In the fourth embodiment as described above, a (001) semiconductor substrate is used, the channel length direction is set in the direction of <100> of this semiconductor substrate, and the source and drain regions are formed by using a silicon compound containing an element having a lattice constant smaller than that of silicon, thereby producing tensile stress in the channel length direction of the channel region. This makes it possible to increase the mobility in a pMOS transistor and nMOS transistor formed on the same semiconductor substrate.

The embodiments of the present invention can provide a semiconductor device capable of increasing the mobility in a pMOS transistor and nMOS transistor formed on the same semiconductor substrate.

Also, the embodiments described above can be practiced either singly or in the form of any appropriate combination. Furthermore, the above embodiments include inventions in various stages. Therefore, these inventions in various stages may also be extracted by appropriately combining a plurality of constituent elements disclosed in the embodiments.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a (001) semiconductor region;
a source region and a drain region formed away from each other in the semiconductor region, a channel region being formed in the semiconductor region between the source region and the drain region, a channel length direction of the channel region being set in a direction of <100> of the semiconductor region, and tensile stress being produced in the channel length direction;
a gate insulating film formed on the semiconductor region between the source region and the drain region; and
a gate electrode formed on the gate insulating film.

2. A semiconductor device comprising:
a (001) semiconductor region;
a source region and a drain region formed away from each other in the semiconductor region, a channel length direction connecting the source region and the drain region being set along a direction of <100> of the semiconductor region;
a gate insulating film formed on the semiconductor region between the source region and the drain region;
a gate electrode formed on the gate insulating film; and
an insulating film which is formed on the source region, the drain region, and the gate electrode, and produces tensile stress in the channel length direction connecting the source region and the drain region in the semiconductor region.

3. The device according to claim 2, wherein the insulating film includes a silicon nitride film.

4. The device according to claim 3, wherein the silicon nitride film includes an HCD—SiN film formed by CVD.

5. The device according to claim 3, wherein the silicon nitride film includes an SiN film formed by plasma CVD which forms more Si—H bonds than N—H bonds.

6. A semiconductor device comprising:
a (001) semiconductor region;
a source region and a drain region formed away from each other in the semiconductor region, a channel length direction connecting the source region and the drain region being set in a direction of <100> of the semiconductor region;
a gate insulating film formed on the semiconductor region between the source region and the drain region;
a gate electrode formed on the gate insulating film; and
an element isolation region formed in a trench formed in the semiconductor region, and including an insulating film, the insulating film producing tensile stress and being in contact with at least a portion of the source region and the drain region.

7. The device according to claim 6, wherein the element isolation region includes a silicon oxide film formed on the silicon nitride film so as to be buried in the trench.

8. The device according to claim 6, wherein the insulating film includes a silicon nitride film.

9. A semiconductor device comprising:
a (001) semiconductor region;
a source region and a drain region formed away from each other in the semiconductor region, a channel length direction connecting the source region and the drain region being set in a direction of <100> of the semiconductor region;
a gate insulating film formed on the semiconductor region between the source region and the drain region; and
a gate electrode formed on the gate insulating film and containing an impurity element which expands the gate electrode upon annealing.

10. The device according to claim 9, wherein the impurity element includes at least one of As and Ge.

11. A semiconductor device comprising:
a (001) semiconductor region;
a source region and a drain region formed away from each other in the semiconductor region, the source region and the drain region having a silicon compound containing an element having a lattice constant smaller than that of silicon, and a channel length direction connecting the source region and the drain region being set in a direction of <100> of the semiconductor region;
a gate insulating film formed on the semiconductor region between the source region and the drain region; and
a gate electrode formed on the gate insulating film.

12. The device according to claim 11, wherein the source region and the drain region are made of silicon carbide.

13. The device according to claim 12, wherein the silicon carbide is formed by epitaxial growth.

14. A semiconductor device comprising:
an n-channel MOS field-effect transistor formed in a (001) semiconductor region, including a first source region and a first drain region formed away from each other in the semiconductor region, a first channel region being formed in the semiconductor region between the first source region and the first drain region, a channel length direction of the first channel region being set in a direction of <100> of the semiconductor region, and tensile stress being produced in the channel length direction,
a first gate insulating film formed on the semiconductor region between the first source region and the first drain region, and
a first gate electrode formed on the first gate insulating film; and
a p-channel MOS field-effect transistor formed in the semiconductor region, including a second source region and a second drain region formed away from each other in the semiconductor region, a second channel region being formed in the semiconductor region between the second source region and the second drain region, a channel length direction of the second channel region being set in the direction of <100> of the semiconductor region, and tensile stress being produced in the channel length direction,
a second gate insulating film formed on the semiconductor region between the second source region and the second drain region, and
a second gate electrode formed on the second gate insulating film.

15. A semiconductor device fabrication method comprising:
forming a gate electrode above a (001) semiconductor region;
forming a source region and a drain region in the semiconductor region along a direction of <100> of the semiconductor region so as to sandwich the semiconductor region below the gate electrode; and
forming, on the source region, the drain region, and the gate electrode, an insulating film which produces tensile stress in a channel length direction connecting the source region and the drain region in the semiconductor region.

16. The fabrication method according to claim 15, wherein the insulating film includes a silicon nitride film and is formed by one of thermal CVD and plasma CVD.

17. A semiconductor device fabrication method comprising:
forming trenches in a (001) semiconductor region;
forming an insulating film in contact with the semiconductor region in the trenches, the insulating film producing tensile stress;
forming a gate electrode above the semiconductor region between the trenches; and
forming a source region and a drain region in the semiconductor region along a direction of <100> of the semiconductor region so as to sandwich the semiconductor region below the gate electrode.

18. A semiconductor device fabrication method comprising:
forming, above a (001) semiconductor region, a gate electrode into which an impurity element which expands upon annealing is doped;
annealing the gate electrode; and
forming a source region and a drain region in the semiconductor region along a direction of <100> of the semiconductor region so as to sandwich the semiconductor region below the gate electrode.

19. The fabrication method according to claim 18, wherein the impurity element is doped into the gate electrode by ion implantation.

20. A semiconductor device fabrication method comprising:
forming a gate electrode above a (001) semiconductor region;
forming a sidewall insulating film on side walls of the gate electrode;
forming grooves in the semiconductor region on sides of the sidewall insulating film; and
forming, in the grooves, a source region and a drain region made of epitaxial layers along a direction of <100> of the semiconductor region so as to sandwich the semiconductor region below the gate electrode.
